(19) United States
(12) Patent Application Publication
(10) Pub. No.: US 2020/0395336 A1
(43) Pub. Date: Dec. 17, 2020

(54) SEMICONDUCTOR APPARATUS AND METHOD OF MANUFACTURING SEMICONDUCTOR APPARATUS

(71) Applicant: FUJITSU LIMITED, Kawasaki-shi (JP)

(72) Inventors: Ayumi Okano, Atsugi (JP); Shinya Sasaki, Ebina (JP); Yoshihiro Nakata, Atsugi (JP); Teru Nakanishi, Isehara (JP)

(73) Assignee: FUJITSU LIMITED, Kawasaki-shi (JP)

(21) Appl. No.: 16/901,381

(22) Filed: Jun. 15, 2020

(30) Foreign Application Priority Data
Jun. 17, 2019 (JP) 2019-112197

(51) Int. Cl. H01L 25/065; H01L 23/16; H01L 23/367; H01L 23/66; H01L 21/50

(52) U.S. Cl. CPC H01L 25/0655; H01L 23/16; H01L 21/50; H01L 23/66; H01L 23/367

(57) ABSTRACT

A semiconductor apparatus includes: a substrate; a plurality of semiconductor devices mounted on a first surface of the substrate; a heat spreader coupled to a second side opposite to a first side, which is coupled to the substrate, of the plurality of semiconductor devices; an underfill provided in a gap between the substrate and the plurality of semiconductor devices; and a heat conductive resin provided between the heat spreader and the underfill.

### CROSS-REFERENCE TO RELATED APPLICATION

This application is based upon and claims the benefit of priority of the prior Japanese Patent Application No. 2019-112197, filed on Jun. 17, 2019, the entire contents of which are incorporated herein by reference.

### FIELD

The present invention is related to a semiconductor apparatus and a method of manufacturing the semiconductor apparatus.

### BACKGROUND

In the related art, there is a semiconductor apparatus including a semiconductor substrate including a plurality of power supply layers/ground layers/wiring layers in which layers neighboring in a vertical direction are insulated from each other through insulating layers, a semiconductor integrated circuit apparatus provided over the semiconductor substrate, and a plurality of capacitors provided around the semiconductor integrated circuit apparatus over the semiconductor substrate.

An example of the related art includes Japanese Laid-open Patent Publication No. 2007-207933.

### SUMMARY

According to an aspect of the embodiments, a semiconductor apparatus includes: a substrate; a plurality of semiconductor devices mounted on a first surface of the substrate; a heat spreader coupled to a second side opposite to a first side, which is coupled to the substrate, of the plurality of semiconductor devices; an underfill provided in a gap between the substrate and the plurality of semiconductor devices; and a heat conductive resin provided between the heat spreader and the underfill.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a diagram illustrating a semiconductor apparatus 100 according to an embodiment.

FIG. 2 is a diagram illustrating a cross section indicated by an arrow A-A of FIG. 1.

FIG. 3 is a diagram illustrating an effect of the semiconductor apparatus 100.

FIGS. 4A and 4B depict a diagram illustrating a method of manufacturing the semiconductor apparatus 100.

FIGS. 5A, 5B, and 5C depict a diagram illustrating cross sections of semiconductor apparatuses 100M1, 100M2, and 100M3 according to modification examples of the embodiment.

### DESCRIPTION OF EMBODIMENT(S)

However, a semiconductor apparatus or related art does not provide in particular a configuration in which an underfill is separated from a heat spreader, and heat is dissipated from the underfill to the heat spreader. For example, when a temperature of a semiconductor device such as a semiconductor integrated circuit apparatus increases due to an increase in an operation frequency or the like, a local temperature increases at a coupling portion between the semiconductor device and a substrate, and the coupling portion may be damaged due to a difference in a line expansion coefficient. The damage to the coupling portion leads to a reduction in reliability of the semiconductor apparatus.

Thus, an object is to provide a semiconductor apparatus with an increased reliability and a method of manufacturing the semiconductor apparatus.

A semiconductor apparatus with a high reliability and a method of manufacturing the semiconductor apparatus.

Hereinafter, embodiments to which a semiconductor apparatus and a method of manufacturing the semiconductor apparatus according to the present invention are applied will be described.

### EMBODIMENTS

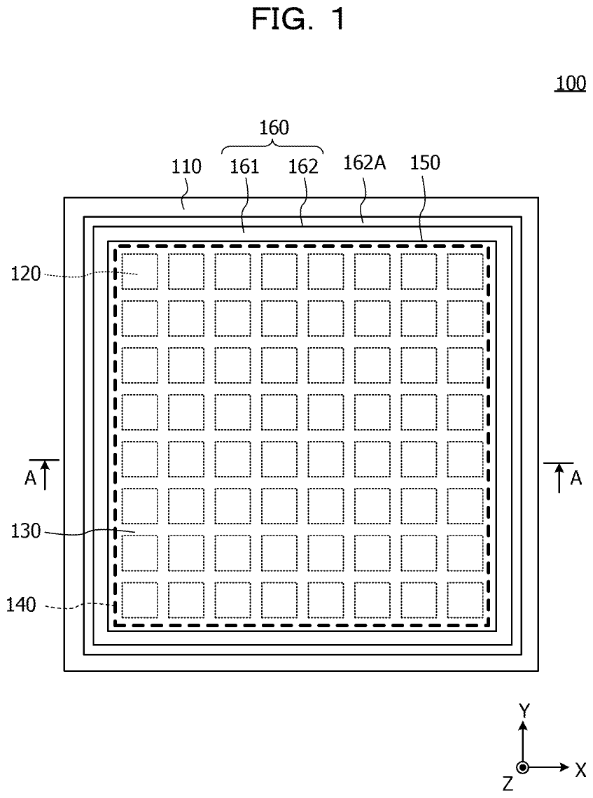

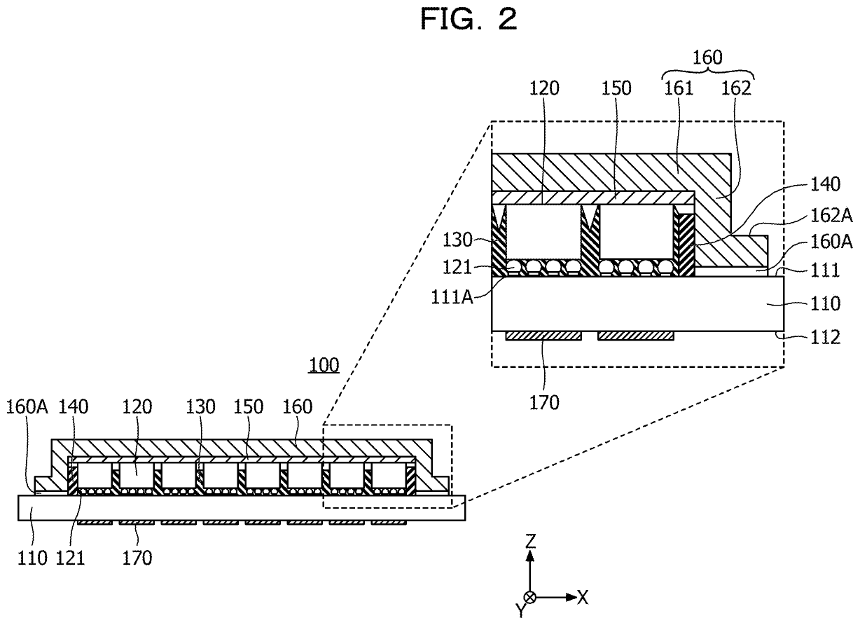

FIG. 1 is a diagram illustrating a semiconductor apparatus 100 according to an embodiment. On the right side of FIG. 1, an enlarged diagram of a part (part surrounded by a dashed line) of the semiconductor apparatus 100 is illustrated. FIG. 2 is a diagram illustrating a cross section indicated by an arrow A-A of FIG. 1.

Hereinafter, an XYZ orthogonal coordinate system will be described. For the sake of convenient description, a +Z direction side is described as an upper side and a −Z direction side is described as a lower side, which does not represent a vertical relationship in many cases. In addition, the plan view indicates an XY plan view.

The semiconductor apparatus 100 includes a substrate 110, semiconductor packages 120, an underfill 130, a heat conductive resin 140, a thermal interface material (TIM) 150, a heat spreader 160, and antennas 170.

Here, as an example, a mode in which the semiconductor apparatus 100 is used for a high-speed wireless communication in a millimeter wave band that is expected to be applied in a fifth generation (5G) communication will be described. The millimeter wave band is, for example, a frequency band of approximately 450 MHz to approximately 6 GHz, a frequency band of approximately 25 GHz to approximately 50 GHz, and a frequency band corresponding thereto.

In a case where the semiconductor apparatus 100 is used for the high-speed wireless communication in the millimeter wave band, a plurality of the semiconductor packages 120 are mounted on the substrate 110 at a high density, the same number of antennas 170 as the number of the semiconductor packages 120 are provided on a bottom surface of the substrate 110, one antenna 170 is coupled to each semiconductor package 120, and processing of a transmission signal and a reception signal is performed by each semiconductor package 120.

In such an application, since a power amplifier is mounted in each semiconductor package 120, the heat generation amount of the semiconductor package 120 increases. The semiconductor apparatus 100 has a heat dissipation structure capable of coping with an application having a large heat generation amount as such. A portion of the power amplifier is realized by, for example, a gallium nitride high-electron-mobility transistor (GaN-HEMT).

In addition, in a case where the semiconductor apparatus 100 is used for the high-speed wireless communication in the millimeter wave band, when the antenna 170 is mounted in the semiconductor apparatus 100, a study is required for the layout such that the heat spreader 160 does not influence radiation characteristics.

Hereinafter, respective units of the semiconductor apparatus 100 having both a heat dissipation structure and satisfactory radiation characteristics of the antenna 170 will be described.

The substrate 110 is, for example a wiring substrate of a flame retardant type 4 (FR-4) standard, and includes a plurality of inner layers. In addition, the substrate 110 includes a top surface 111 and a bottom surface 112. The top surface 111 is an example of a first surface, and the bottom surface 112 is an example of a second surface.

The pads 111A (see the enlarged diagram of FIG. 1) provided on the top surface 111 of the substrate 110 are coupled to the pads of the bottom surface of the semiconductor package 120 through solder balls 121. Hereinafter, the pads 111A and the solder balls 121, and the solder balls 121 and pads on the bottom surface of the semiconductor package 120 are referred to as a coupling portion between the substrate 110 and the semiconductor package 120.

For example, a total of 64 semiconductor packages 120 of eight semiconductor packages 120 in the X direction and eight semiconductor packages 120 in the Y direction are arranged in a matrix form in plan view. As such, 64 semiconductor packages 120 are mounted on the top surface 111 of the substrate 110.

In addition, the antennas 170 are provided on the bottom surface 112 of the substrate 110. A total of 64 antennas 170 of eight antennas 170 in the X direction and eight antennas 170 in the Y direction are arranged in a matrix in plan view. The 64 antennas 170 are respectively coupled to 64 semiconductor packages 120 via wires in the inside of the substrate 110.

The semiconductor package 120 is, for example, an electronic component packaged by covering a plurality of semiconductor devices mounted on a substrate with a sealing resin or the like. That is, the semiconductor package 120 includes the plurality of semiconductor devices. Here, The semiconductor package 120 includes, for example, a power amplifier as one of a plurality of semiconductor devices.

In the semiconductor package 120, the pads on the bottom surface thereof are coupled to the pads 111A on the top surface 111 of the substrate 110 through the solder balls 121, and are further coupled to the antennas 170 provided on the bottom surface 112 of the substrate 110 through wires in the inside of the substrate 110.

For example, a fan-out wafer-level packaging (FOWLP), a wafer-level chip-scale (or size) package (WL-CSP), a flip chip ball grid array (FC-BGA), and the like may be employed as a specific configuration of the semiconductor package 120.

Here, the semiconductor device is a device which is manufactured by using a semiconductor manufacturing technology and which is not packaged like the semiconductor package 120, and is an integrated circuit (IC) such as a power amplifier, a logic IC, a microprocessor, or a memory in many cases.

However, the semiconductor device may be one (discrete) having a single function such as a transistor or a diode. For example, such a semiconductor device is obtained by forming a semiconductor on a silicon substrate by a semiconductor manufacturing technique and then, individualizing the semiconductor.

As such, since the semiconductor package 120 includes a plurality of semiconductor devices, the semiconductor package 120 may be handled as a semiconductor device. Therefore, the semiconductor package 120 is an example of the semiconductor device. In addition, a lower side of the semiconductor package 120 is an example of a first side, and an upper side is an example of a second side.

Further, although a mode in which the semiconductor apparatus 100 includes the semiconductor package 120 is described herein, the semiconductor apparatus 100 may include a single semiconductor device instead of at least one semiconductor package 120.

The underfill 130 is filled (provided) between the top surface 111 of the substrate 110 and the bottom surface of the semiconductor package 120 and is provided between the side surfaces of the semiconductor package 120. That is, the underfill 130 is provided on a gap between the substrate 110 and the semiconductor package 120 and provided on a side surface of the semiconductor package 120. The underfill 130 covers and protects a coupling portion (the pads 111A and solder balls 121, and the solder balls 121 and the pads on the bottom surface of the semiconductor package 120) between the substrate 110 and the semiconductor package 120, thereby, being provided to reduce stress.

For example, a composite resin that uses an epoxy resin as a main material may be used as the underfill 130. In addition, in order to suppress damage to the coupling portion between the substrate 110 and the semiconductor package 120 due to a thermal expansion, it is preferable that the coupling portion is formed of a material having a thermal expansion coefficient close to thermal expansion coefficients of the substrate 110 and the semiconductor package 120.

As illustrated in FIG. 1, the heat conductive resin 140 is provided in a rectangular ring shape in plan view. As illustrated in FIG. 1, the heat conductive resin 140 surrounds outsides of the 28 semiconductor packages 120 arranged in a rectangular ring shape at the outermost side in plan view among the 64 semiconductor packages 120 arranged in a matrix form, and is provided to couple the underfill 130 located on side surfaces of the 28 semiconductor packages 120 to an inner wall surface of the side wall portion 162 of the heat spreader 160.

The heat conductive resin 140 is provided to guide (dissipate) the heat, which is conducted from the semiconductor package 120 to the underfill 130, to the heat spreader 160. By doing so, an increase in temperature of the substrate 110, the semiconductor package 120, and the underfill 130 is suppressed to reduce a thermal expansion, and thus, damage to the coupling portion (the pads 111A and the solder balls 121, and the solder balls 121 and the pads on the bottom surface of the semiconductor package 120) between the substrate 110 and the semiconductor package 120 is suppressed.

The heat conductive resin 140 has, for example, a thermal conductivity higher than a thermal conductivity of the underfill 130. By efficiently conducting the heat generated by the semiconductor package 120 and the solder balls 121 from the underfill 130 to the heat spreader 160 through the heat conductive resin 140, thermal expansions of the substrate 110, the semiconductor package 120, and the underfill 130 are suppressed to suppress damage to the coupling portion between the substrate 110 and the semiconductor package 120, and thus, reliability of the coupling portion is increased.

From such a viewpoint, it is preferable that thermal conductivity of the heat conductive resin 140 is 1 W/m·K or greater. For example, an adhesive containing metal particles such as an Ag (silver) paste and a Cu (copper) paste may be used as the heat conductive resin 140. In addition, the heat conductive resin 140 is not limited to a material containing the metal particles and may be, for example, an adhesive containing non-metallic particles having a relatively high thermal conductivity such as silica or alumina as a filler.

The heat conductive resin 140 is formed by thermally curing the above-described adhesive between the underfill 130 on the side surface of the semiconductor package 120 and the inner wall surface of the side wall portion 162 of the heat spreader 160. Thereby, the underfill 130 on the side surface of the semiconductor package 120 and the inner wall surface of the side wall portion 162 of the heat spreader 160 are bonded to each other by the heat conductive resin 140.

In addition, when the heat conductive resin 140 is provided as such, it is preferable that the heat conductive resin 140 is in contact with the top surface 111 of the substrate 110 as illustrated in the enlarged diagram of FIG. 2. This is for efficiently guiding heat conducted from the semiconductor package 120 to the substrate 110 to the heat spreader 160. By doing so, an increase in temperature of the underfill 130 resulting in suppress of damage to the coupling portion between the substrate 110 and the semiconductor package 120 is suppressed, and thus, reliability of the coupling portion may increase.

The TIM 150 is an example of a heat conductive sheet and is a sheet member having a rectangular shape in plan view as illustrated in FIG. 1. As illustrated in FIG. 2, the TIM 150 is provided between the top surfaces of the 64 semiconductor packages 120 and the bottom surface of a base portion 161 of the heat spreader 160.

The TIM 150 is provided to reduce a thermal resistance of an interface between the semiconductor package 120 and the heat spreader 160 and to efficiently induce heat generated by the semiconductor package 120 to the heat spreader 160. For example, an indium sheet may be used as the TIM 150, but a sheet formed of other metal or non-metal may be used. In the TIM 150, the top surface and the bottom surface thereof are coated with an adhesive to bond the semiconductor package 120 and the heat spreader 160 together. Further, the TIM 150 may not be coated with an adhesive.

The heat spreader 160 includes the base portion 161 and the side wall portion 162. The base portion 161 is located at the center of the heat spreader 160 in plan view and is a rectangular plate-shaped portion located above the 64 semiconductor packages 120. The side wall portion 162 is a wall portion extending downwardly from a periphery of the four sides of the base portion 161, and an extension portion 162A extending outwards in plan view is provided at a lower end. As illustrated in FIG. 2, the extension portion 162A protrudes outwards at the lower end of the side wall portion 162 in XZ cross section diagram.

The heat spreader 160 is fixed to the substrate 110 by sealing and bonding between bottom surfaces of the side wall portion 162 and the extension portion 162A and the top surface 111 of the substrate 110 with a sealant 160A. In addition, in this state, the TIM 150 is interposed between the bottom surface of the base portion 161 and the top surfaces of the 64 semiconductor packages 120, and the bottom surface of the base portion 161 and the top surface of the semiconductor package 120 are bonded to each other by the TIM 150. In addition, in this state, the 64 semiconductor packages 120 are contained in a space sealed by the substrate 110 and the heat spreader 160.

Although a material of the heat spreader 160 is not limited in particular as long as thermal conductivity is high, in order to ensure high heat dissipation, it is possible to use a metal having thermal conductivity of 50 W/m·K or greater, an alloy including the metal, or a non-metal having high thermal conductivity such as graphite, and furthermore, it is preferable to be a material close to thermal expansion coefficients of the substrate 110 and the semiconductor package 120 so as to suppress generation of stress due to a difference the thermal expansion coefficients at the time of mounting.

The antennas 170 are provided on a bottom surface 112 of the substrate 110. The antennas 170 are, for example, a patch antenna having a rectangular shape in plan view. Here, for example, the antennas 170 are antennas for 5G communication and are respectively coupled to the semiconductor packages 120 through wires in the inside of the substrate 110, and thereby, a total of 64 antennas 170 of 8*8 are arranged in a matrix in the X direction and the Y direction 8 by one.

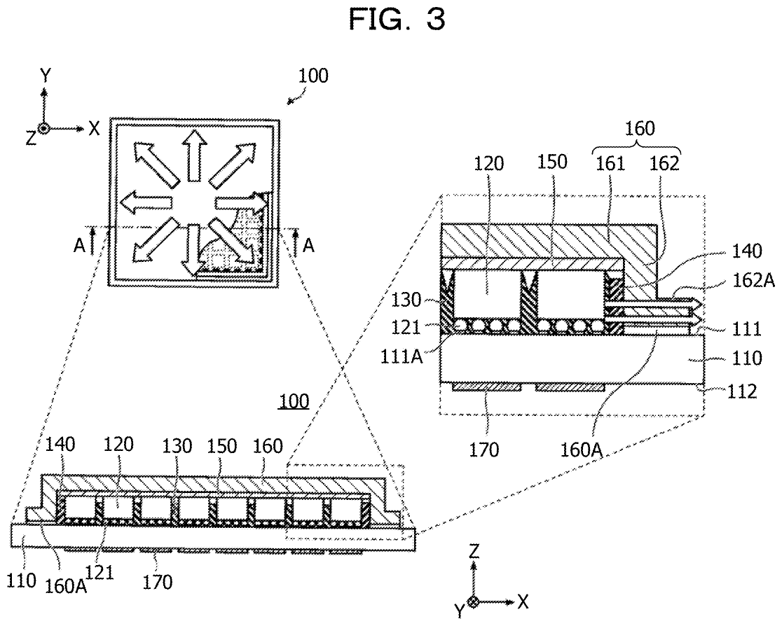

FIG. 3 is a diagram illustrating an effect of the semiconductor apparatus 100. The semiconductor apparatus 100 is schematically illustrated on the upper side of FIG. 3. As illustrated in the upper side of FIG. 3, in the semiconductor apparatus 100, heat generated according to an operation of the semiconductor package 120 is transferred from the center to the outside of the semiconductor apparatus 100 in plan view as indicated by an arrow. Therefore, the heat is locally concentrated on the periphery of the 28 semiconductor packages 120 located on the outermost side among the 64 semiconductor packages 120.

Although the semiconductor apparatus 100 includes the underfill 130 so as to suppress damage to the coupling portion between the substrate 110 and the semiconductor package 120, in a case where the heat generation amount is large, deformation and the like due to thermal expansions of the substrate 110, the semiconductor package 120, and the underfill 130 cause stress, and thereby, the coupling portion between the substrate 110 and the semiconductor package 120 is damaged.

Therefore, the semiconductor apparatus 100 is focused on the 28 semiconductor packages 120 which are located on the outermost side among the 64 semiconductor packages 120 and on which heat is locally concentrated, and there is provided the heat conductive resin 140 for coupling between the underfill 130 located on the side surfaces of the 28 semiconductor packages 120 and the inner wall surface of the side wall portion 162 of the heat spreader 160.

By providing the heat conductive resin 140, the locally concentrated heat is conducted from the underfill 130 located on the side surface of the 28 semiconductor packages 120 to the heat spreader 160 via the heat conductive resin 140, as illustrated in the enlarged diagram on the lower side in FIG. 3.

Therefore, heat may be efficiently dissipated from the underfill 130 to the heat spreader 160, deformation may be suppressed by suppressing an increase in temperatures of the substrate 110, the semiconductor package 120, and the underfill 130, and damage to the coupling portion between the substrate 110 and the semiconductor package 120 may be suppressed.

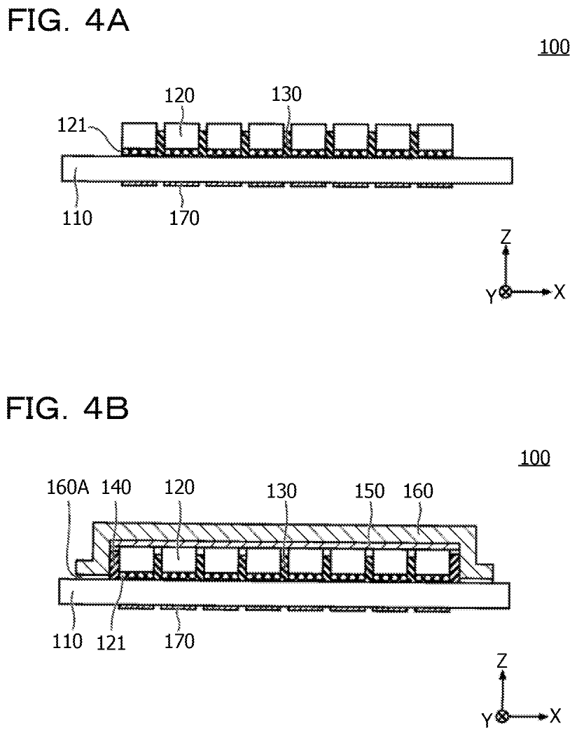

Next, a method of manufacturing the semiconductor apparatus 100 will be described. FIG. 4 (i.e., FIGS. 4A and 4B) is a diagram illustrating the method of manufacturing the semiconductor apparatus 100.

First, as illustrated in FIG. 4A, the semiconductor package 120 is mounted on the top surface 111 of the substrate 110 on which the antennas 170 are mounted on the bottom surface 112 via the solder balls 121, and a material (for example, an epoxy resin) for the underfills 130 is filled between the substrate 110 and the semiconductor packages 120 and cured by thermal processing, and thereby, the underfills 130 are formed.

Next, in a state where a material (for example, Ag paste) for the heat conductive resin 140 is applied to the side surface of the underfill 130 covering the coupling portions between the semiconductor packages 120 and the side surfaces of the outermost semiconductor packages 120 and the TIM 150 is placed on the top surfaces of the semiconductor packages 120, the heat spreader 160 is fixed on the substrate 110 by using the sealant 160A, and furthermore, the material for the heat conductive resin 140 is cured by thermal processing, and thereby, the heat conductive resin 140 is formed and the semiconductor apparatus 100 is manufactured as illustrated in FIG. 4B.

Next, the semiconductor apparatus 100 of the examples 1 to 3 and the semiconductor apparatus of the comparative examples 1 and 2 are manufactured, and a temperature of the top surface of the heat spreader 160 is measured by simulation.

In the semiconductor apparatus 100 according to example 1, a thickness of the substrate 10 is 1.0 mm, a plane size thereof is 24 mm square, a thickness of the semiconductor package 120 by FOWLP is 1.0 mm, a plane size thereof is 10 mm square, the solder ball 121 is φ0.5 mm, a bump pitch (X direction) is 1.5 mm, and thermal conductivity of the underfill 130 is 2.5 W/mK. In addition, a thickness of the heat conductive resin 140 is 1.0 mm, a width thereof in the X direction and the width in the Y direction is 2.0 mm, thermal conductivity thereof is 5 W/mK, a thickness of the TIM 150 is 0.1 mm, and a plane size of the heat spreader 160 is 24 mm square.

A semiconductor apparatus that does not include the heat conductive resin 140 is manufactured as the semiconductor apparatus according to comparative example 1. The semiconductor is the same as the semiconductor apparatus 100 except that the heat conductive resin 140 is not included therein.

In the semiconductor apparatus 100 according to example 1 and the semiconductor apparatus according to comparative example 1, a temperature is measured by simulation under a condition that only one of the 64 semiconductor packages 120 operates to set a heat generation amount to 10 W.

A temperature of the top surface of the heat spreader 160 of the semiconductor apparatus 100 according to example 1 is 145° C., and a temperature of the top surface of the heat spreader 160 of the semiconductor apparatus according to comparative example 1 is 160° C. Therefore, it is confirmed that by including the heat conductive resin 140 as in the semiconductor apparatus 100 according to example 1, a temperature of the heat spreader 160 is lowered by 15° C. compared to the semiconductor apparatus according to comparative example 1, and a heat dissipation effect by the heat conductive resin 140 is obtained.

Here, although the temperature is measured by simulation under the condition that only one of the 64 semiconductor packages 120 operates and the heat generation amount is 10 W, the 64 semiconductor packages 120 are heated in the actual operation environment, and thus, the temperature of the heat spreader 160 is further increased, and a temperature difference between the heat spreader 160 of the semiconductor apparatus 100 according to example 1 and the heat spreader 160 of the semiconductor apparatus according to comparative example 1 is further increased.

In addition, the semiconductor apparatus 100 according to example 2 has the same structure as the structure of example 1, but the heat generation amount of one of the 64 semiconductor packages 120 is set to 3 W.

In addition, while the semiconductor apparatus according to comparative example 2 has the same structure as the structure of the semiconductor apparatus according to comparative example 1, the heat generation amount of one of the 64 semiconductor packages 120 is set to 3 W.

A temperature of a top surface of the heat spreader 160 of the semiconductor apparatus 100 according to example 2 is 95° C., and a temperature of a top surface of the heat spreader 160 of the semiconductor apparatus according to comparative example 2 is 105° C. Therefore, by including the heat conductive resin 140 as in the semiconductor apparatus 100 of example 2, it is confirmed that the temperature of the heat spreader 160 is lowered by 10° C. compared to the temperature of the semiconductor apparatus according to comparative example 2 and a heat dissipation effect is obtained by the heat conductive resin 140 even in a case where the heat generation amount of the semiconductor package 120 is lowered.

In the semiconductor apparatus 100 according to example 3, the thermal conductivity of the underfill 130 is reduced to 0.6 W/mK.

A temperature of a top surface of the heat spreader 160 is 100° C. under a condition that a heat generation amount of one of the 64 semiconductor packages 120 is set to 3 W and is lowered by 5° C. more than the temperature of the semiconductor apparatus according to comparative example 2. Thereby, it is confirmed that the semiconductor apparatus 100 is improved in heat dissipation effect by including the heat conductive resin 140.

As described above, according to the embodiment, by providing the heat conductive resin 140 between the underfill 130 and the heat spreader 160, heat transferred from the semiconductor package 120 to the underfill 130 may be efficiently conducted to the heat spreader 160. As a result, the conducted heat is released to atmosphere from the heat spreader 160.

Therefore, an increase in temperatures of the substrate 110, the semiconductor package 120, and the underfill 130 is suppressed, and damage to a bonding portion between the substrate 110 and the semiconductor package 120 due to a difference in thermal expansion coefficient between the substrate 110, the semiconductor package 120, and the underfill 130 may be suppressed.

Thus, it is possible to provide the semiconductor apparatus 100 with increased reliability and a method of manufacturing the semiconductor apparatus 100.

In addition, since a lower end of the heat conductive resin 140 is in contact with a surface of the substrate 110, it is possible to assist in induction of heat from the substrate 110 to the heat spreader 160, and thus, it is possible to suppress damages to the bonding portion between the substrate 110 and the semiconductor package 120 due to a difference in thermal expansion coefficient between the substrate 110, the semiconductor package 120, and the underfill 130.

Here, since the antennas 170 are provided on the bottom surface 112 of the substrate 110, the heat spreader 160 may not be disposed on a lower side of the substrate 110. This is because the heat spreader 160 has an influence on radiation characteristics of the antennas 170.

Therefore, the heat spreader 160 is provided on an upper side of the substrate 110. Under such structural restrictions, by providing the heat conductive resin 140 between the underfill 130 and the heat spreader 160, heat conducted from the semiconductor package 120 to the underfill 130 may be efficiently conducted to the heat spreader 160, and thus, reliability of the semiconductor apparatus 100 may be increased.

In addition, in other words, by providing the heat conductive resin 140, heat may be conducted from the underfill 130 to the heat spreader 160 provided on the upper side of the substrate 110, and thus, it is possible to realize a configuration in which the antennas 170 are mounted on the bottom surface 112 of the substrate 110.

In addition, the heat conductive resin 140 is provided between a portion on an outer side surface of the semiconductor packages 120 located on the outermost side of the underfill 130 in plan view and the heat spreader 160. The semiconductor package 120 located on the outermost side in plan view is a portion where heat is most concentrated in plan view. Then, since the heat conductive resin 140 receives and passes heat between the underfill 130 and the heat spreader 160 which are in contact with the outermost surfaces of the semiconductor packages 120 located on outermost side surface in plan view, a heat dissipation efficiency is increased, damage to the coupling portion between the substrate 110 and the semiconductor package 120 is suppressed, and reliability of the semiconductor apparatus 100 may be increased.

In addition, the heat spreader 160 has a side wall portion 162 which is provided to face the top surface 111 of the substrate 110 on the outside of the 64 semiconductor package 120 in plan view, and which is coupled to the top surface 111. With such a configuration, heat is directly conducted from the substrate 110 to the heat spreader 160, and the 64 semiconductor packages 120 are disposed in a space sealed by the substrate 110 and the heat spreader 160.

Therefore, a heat dissipation efficiency due to the heat spreader 160 may be increased, the semiconductor package 120 may be disposed within the sealed space, and thus, it is possible to provide the semiconductor apparatus 100 with a high reliability.

Further, in the above description, the example is described in which the heat conductive resin 140 is provided between the portion on the outer side surface of the semiconductor packages 120 located on the outermost side of the underfill 130 in plan view and the heat spreader 160. This is because heat is most concentrated at this location.

However, a location of the heat conductive resin 140 may be even more inside in plan view. Since the underfill 130 exists between the 64 semiconductor packages 120, when a portion of any one of the underfills 130 and the heat spreader 160 are coupled by the heat conductive resin 140, the heat of the underfill 130 may be efficiently conducted to the heat spreader 160.

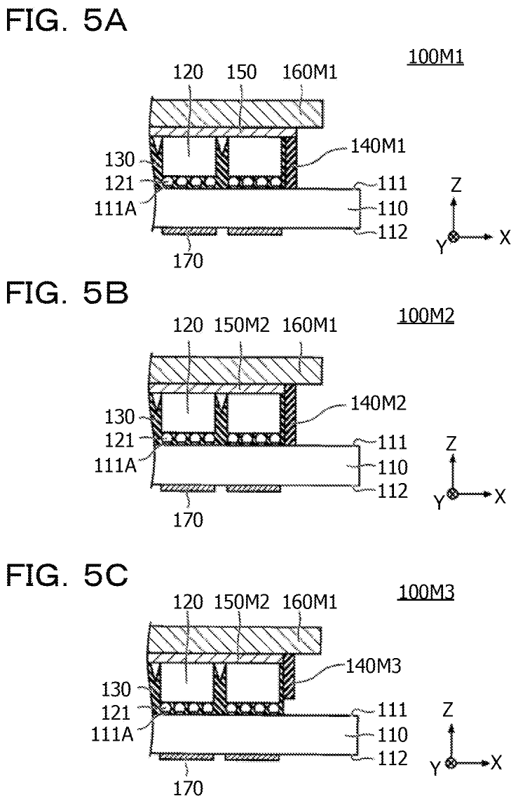

In addition, the heat conductive resin 140 may be modified as illustrated in FIGS. 5A to 5C. FIG. 5 (i.e., FIGS. 5A, 5B, and 5C) depicts a diagram illustrating a cross section of semiconductor apparatuses 100M1, 100M2, and 100M3 according to a modification example of the embodiment. FIGS. 5A, 5B, and 5C illustrate cross sectional structures corresponding to the enlarged diagram of FIG. 2. Here, points different from the semiconductor apparatus 100 according to the embodiment will be mainly described.

The semiconductor apparatus 100M1 illustrated in FIG. 5A includes the substrate 110, the semiconductor package 120, the underfill 130, a heat conductive resin 140M1, the TIM 150, a heat spreader 160M1, and the antennas 170.

In the semiconductor apparatus 100M1, the heat spreader 160M1 is a plate-shaped member having a portion corresponding to the base portion 161 in FIG. 2 without having the side wall portion 162 (see FIG. 2). In addition, the heat conductive resin 140M1 extends upward until the heat conductive resin comes into contact with a bottom surface of the TIM 150. The semiconductor apparatus 100M1 may be manufactured in the same manner as the semiconductor apparatus 100 illustrated in FIGS. 1 and 2.

In the semiconductor apparatus 100M1, the underfill 130 is coupled to the heat spreader 160M1 through the heat conductive resin 140M1 and the TIM 150. The heat conductive resin 140M1 is provided between the heat spreader 160M1 and the underfill 130 in such a configuration.

Heat conducted from the semiconductor package 120 to the underfill 130 is dissipated to the heat spreader 160M1 through the heat conductive resin 140M1 and the TIM 150. Therefore, an increase in temperatures of the substrate 110, the semiconductor package 120, and the underfill 130 is suppressed, and damage to a bonding portion between the substrate 110 and the semiconductor package 120 due to a difference in thermal expansion coefficient between the substrate 110, the semiconductor package 120, and the underfill 130 may be suppressed.

Thus, it is possible to provide the semiconductor apparatus 100M1 having an increased reliability and a method of manufacturing the semiconductor apparatus 100M1.

The semiconductor apparatus 100M2 illustrated in FIG. 5B includes the substrate 110, the semiconductor packages 120, the underfill 130, a heat conductive resin 140M2, a TIM 150M2, the heat spreader 160M1, and the antennas 170.

In the semiconductor apparatus 100M2, the TIM 150M2 is a size located on the 64 semiconductor packages 120 in plan view, and does not extend outside the 64 semiconductor packages 120 in the X direction and the Y direction in plan view.

In addition, the heat conductive resin 140M2 extends upward until the heat conductive resin comes into contact with the bottom surface of the heat spreader 160M1. That is, the heat conductive resin 140M2 is directly coupled to the heat spreader 160M1 at a portion where the TIM 150 is not provided in plan view. The semiconductor apparatus 100M2 may be manufactured in the same manner as the semiconductor apparatus 100 illustrated in FIGS. 1 and 2.

In the semiconductor apparatus 100M2, the underfill 130 is coupled to the heat spreader 160M1 through the heat conductive resin 140M2. The heat conductive resin 140M2 is provided between the heat spreader 160M1 and the underfill 130 in such a configuration.

Heat conducted from the semiconductor package 120 to the underfill 130 is dissipated to the heat spreader 160M1 through the heat conductive resin 140M2. Therefore, an increase in temperatures of the substrate 110, the semiconductor package 120, and the underfill 130 is suppressed, and damage to a bonding portion between the substrate 110 and the semiconductor package 120 due to a difference in thermal expansion coefficient between the substrate 110, the semiconductor package 120, and the underfill 130 may be suppressed.

Thus, it is possible to provide the semiconductor apparatus 100M2 having an increased reliability and a method of manufacturing the semiconductor apparatus 100M2.

The semiconductor apparatus 100M3 illustrated in FIG. 5C includes the substrate 110, the semiconductor package 120, the underfill 130, a heat conductive resin 140M3, the TIM 150M2, the heat spreader 160M1, and the antennas 170.

In the semiconductor apparatus 100M3, the heat conductive resin 140M3 is not in contact with and separated from the top surface 111 of the substrate 110. The heat conductive resin 140M3 extends upward from a location offset upwards from the top surface 111 of the substrate 110 until coming into contact with a bottom surface of the heat spreader 160M1. The semiconductor apparatus 100M3 may be manufactured in the same manner as the semiconductor apparatus 100 illustrated in FIGS. 1 and 2.

In the semiconductor apparatus 100M3, the underfill 130 is coupled to the heat spreader 160M1 through the heat conductive resin 140M3. The heat conductive resin 140M3 is provided between the heat spreader 160M1 and the underfill 130 in such a configuration.

Heat conducted from the semiconductor package 120 to the underfill 130 is dissipated to the heat spreader 160M1 through the heat conductive resin 140M3. Therefore, an increase in temperatures of the substrate 110, the semiconductor package 120, and the underfill 130 is suppressed, and damage to a bonding portion between the substrate 110 and the semiconductor package 120 due to a difference in thermal expansion coefficient between the substrate 110, the semiconductor package 120, and the underfill 130 may be suppressed.

Thus, it is possible to provide the semiconductor apparatus 100M3 having an increased reliability and a method of manufacturing the semiconductor apparatus 100M3.

As described above, a semiconductor apparatus and a method of manufacturing the semiconductor apparatus according to the exemplary embodiment of the present invention are described, and the present invention is not limited to the specifically disclosed embodiments, and various modifications and changes may be made without departing from the scope of the claims.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A semiconductor apparatus, comprising:
a substrate;
a plurality of semiconductor devices mounted on a first surface of the substrate;
a heat spreader coupled to a second side opposite to a first side, which is coupled to the substrate, of the plurality of semiconductor devices;
an underfill provided in a gap between the substrate and the plurality of semiconductor devices; and
a heat conductive resin provided between the heat spreader and the underfill.

2. The semiconductor apparatus according to claim 1,
wherein thermal conductivity of the heat conductive resin is higher than thermal conductivity of the underfill.

3. The semiconductor apparatus according to claim 1, further comprising:
a heat conductive sheet provided between the heat spreader and the second side of the plurality of semiconductor devices,
wherein the heat conductive resin is coupled to the heat spreader through the heat conductive sheet, or the heat conductive resin is directly coupled to the heat spreader at a portion where the heat conductive sheet is not provided in plan view.

4. The semiconductor apparatus according to claim 1,
wherein the underfill is provided to further surround an outer side surface of the semiconductor devices located on an outermost side in plan view among the plurality of semiconductor devices in the plan view, and
wherein the heat conductive resin is provided between the heat spreader and a portion of the underfill which is located at the outer side surface of the semiconductor device located on the outermost side in the plan view.

5. The semiconductor apparatus according to claim 1,
wherein the heat spreader further includes a side wall portion that is provided toward the first surface of the substrate outside the plurality of semiconductor devices in plan view, and is coupled to the first surface, and
wherein the plurality of semiconductor devices are disposed in a space sealed by the substrate and the heat spreader.

6. The semiconductor apparatus according to claim 1, further comprising:
an antenna provided on a second surface of the substrate.

7. A method of manufacturing a semiconductor apparatus, the method comprising:
mounting a plurality of semiconductor devices on a first surface of a substrate;
forming an underfill in a gap between the substrate and the plurality of semiconductor devices;
forming a heat conductive resin coupled to the underfill; and
mounting a heat spreader that is coupled to a second side opposite to a first side, which is coupled to the substrate, of the plurality of semiconductor devices, and is coupled to the heat conductive resin.
